(19) United States
(12) Patent Application Publication
(10) Pub. No.: US 2026/0323822 A1
(43) Pub. Date: Oct. 15, 2026

(54) FLEXIBLE PRINTED CIRCUIT BOARD AND SEMICONDUCTOR PACKAGE AND ELECTRONIC DEVICE INCLUDING THE SAME

(71) Applicant: STEMCO CO., LTD., Cheongju-si (KR)

(72) Inventors: Jae Joon LIM, Cheongju-si (KR); Woon Bae KIM, Cheongju-si (KR); Dong Ki KIM, Cheongju-si (KR); Sung Chul HONG, Cheongju-si (KR); Jung Shik LEE, Cheongju-si (KR); Young Ha OUM, Cheongwon-gun (KR)

(73) Assignee: STEMCO CO., LTD., Cheongju-si (KR)

(21) Appl. No.: 19/242,109

(22) Filed: Jun. 18, 2025

(30) Foreign Application Priority Data
Apr. 15, 2025 (KR) 10-2025-0048775

(51) Int. Cl. H05K 1/03; H05K 1/18

(52) U.S. Cl. CPC H05K 1/0393; H05K 1/181; H05K 2201/09036; H05K 2201/09045; H05K 2201/10734

(57) ABSTRACT

A flexible printed circuit board (FPCB) capable of securing bendability while improving rebound force characteristics, and a semiconductor package and electronic device including the same are provided. The FPCB includes: a base film in which a bending area and a non-bending area are defined; a first wiring pattern layer formed on a first surface of the base film; a first protective layer formed on the first wiring pattern layer; and a recess portion formed in the bending area on a second surface of the base film and including a plurality of recesses, wherein the plurality of recesses are spaced apart from each other and are formed in a dot shape.

### CROSS-REFERENCE TO RELATED APPLICATION

This application claims priority from Korean Patent Application No. 10-2025-0048775 filed on Apr. 15, 2025 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a flexible printed circuit board (FPCB) with improved rebound characteristics, and a semiconductor package and electronic device including the same.

### 2. Description of the Related Art

Chip-on-film (COF) refers to a semiconductor chip mounted on a flexible, thin-film type flexible printed circuit board (FPCB), and is generally applied in a bent shape to the bezel area of an electronic device, such as a display device including an LCD or OLED or a mobile device, to serve the role of transmitting signals between a panel and a main circuit board.

Recently, as the trend of full screen, which aims to reduce the bezel size of a panel and maximize the display area, continues, a problem has arisen in which the rebound force of a COF positioned in the narrow bezel area in a bent state increases. This has become a factor that imposes physical stress on circuit wirings or degrades bonding reliability with other components.

### SUMMARY

One objective of the present disclosure is to provide a flexible printed circuit board (FPCB) capable of improving rebound characteristics while securing bendability, and a semiconductor package and an electronic device including the same.

The objectives of the present disclosure are not limited to those mentioned above, and other objectives not explicitly stated will be clearly understood by those skilled in the art based on the following description.

According to an aspect of the present disclosure, an FPCB includes: a base film in which a bending area and a non-bending area are defined; a first wiring pattern layer formed on a first surface of the base film; a first protective layer formed on the first wiring pattern layer; and a recess portion formed in the bending area on a second surface of the base film and including a plurality of recesses, wherein the plurality of recesses are spaced apart from each other and are formed in a dot shape.

According to another aspect of the present disclosure, an FPCB includes: a base film in which a bending area and a non-bending area are defined; a first wiring pattern layer formed on a first surface of the base film; a first protective layer formed on the first wiring pattern layer; and a recess portion formed in the bending area on a second surface of the base film and including at least one recess, wherein the at least one recess is continuously formed in a line shape along a first direction or a second direction of the base film.

According to yet another aspect of the present disclosure, a semiconductor package includes: the FPCB according to one or another aspect of the present disclosure; a semiconductor chip mounted on the FPCB; and bumps electrically connecting the FPCB and the semiconductor chip.

According to still another aspect of the present disclosure, an electronic device includes the semiconductor package according to yet another aspect of the present disclosure.

According to the present disclosure, the following effects can be obtained.

First, it is possible to reduce the rebound force generated during bending with a recess portion formed in a bending region of an FPCB.

Second, since a protective layer is formed to prevent a plating layer from being formed in the bending region of the FPCB, it is possible to prevent cracks from occurring in the plating layer due to tensile stress of a base film.

Third, stress increased by the thickness of the protective layer in the bending region can be alleviated through the recess portion.

Fourth, not only can rebound characteristics of the FPCB and crack issues in the plating layer be improved through the protective layer and the recess portion, but flexibility can also be secured, thereby enhancing the reliability of a product such as a semiconductor package including a chip-on-film (COF).

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing exemplary embodiments thereof in detail with reference to the attached drawings, in which:

FIG. 1 is a first exemplary view for explaining the structure of a flexible printed circuit board (FPCB) according to some embodiments of the present disclosure;

FIG. 2 is a second exemplary view for explaining the structure of the FPCB according to some embodiments of the present disclosure;

FIG. 3 is a first exemplary view for explaining various structural implementations of a protective layer forming the FPCB according to some embodiments of the present disclosure;

FIG. 4 is a second exemplary view for explaining various structural implementations of the protective layer forming the FPCB according to some embodiments of the present disclosure;

FIG. 5 is a third exemplary view for explaining various structural implementations of the protective layer forming the FPCB according to some embodiments of the present disclosure;

FIG. 6 is a fourth exemplary view for explaining various structural implementations of the protective layer forming the FPCB according to some embodiments of the present disclosure;

FIG. 7 is a first exemplary view for explaining various structural implementations of a recess portion forming the FPCB according to some embodiments of the present disclosure;

FIG. 8 is a second exemplary view for explaining various structural implementations of the recess portion forming the FPCB according to some embodiments of the present disclosure;

FIG. 9 is a third exemplary view for explaining various structural implementations of the recess portion forming the FPCB according to some embodiments of the present disclosure;

FIG. 10 is a fourth exemplary view for explaining various structural implementations of the recess portion forming the FPCB according to some embodiments of the present disclosure;

FIG. 11 is a fifth exemplary view for explaining various structural implementations of the recess portion forming the FPCB according to some embodiments of the present disclosure;

FIG. 12 is a sixth exemplary view for explaining various structural implementations of the recess portion forming the FPCB according to some embodiments of the present disclosure;

FIG. 13 is a seventh exemplary view for explaining various structural implementations of the recess portion forming the FPCB according to some embodiments of the present disclosure;

FIG. 14 is an eighth exemplary view for explaining various structural implementations of the recess portion forming the FPCB according to some embodiments of the present disclosure;

FIG. 15 is a ninth exemplary view for explaining various structural implementations of the recess portion forming the FPCB according to some embodiments of the present disclosure;

FIG. 16 is a tenth exemplary view for explaining various structural implementations of the recess portion forming the FPCB according to some embodiments of the present disclosure;

FIG. 17 is an eleventh exemplary view for explaining various structural implementations of the recess portion forming the FPCB according to some embodiments of the present disclosure;

FIG. 18A is a twelfth exemplary view for explaining various structural implementations of the recess portion forming the FPCB according to some embodiments of the present disclosure;

FIG. 18B is a thirteenth exemplary view for explaining various structural implementations of the recess portion forming the FPCB according to some embodiments of the present disclosure;

FIG. 18C is a fourteenth exemplary view for explaining various structural implementations of the recess portion forming the FPCB according to some embodiments of the present disclosure;

FIG. 19 is a third exemplary view for explaining various structural implementations of the FPCB according to some embodiments of the present disclosure;

FIG. 20 is a fourth exemplary view for explaining various structural implementations of the FPCB according to some embodiments of the present disclosure;

FIG. 21 is a fifth exemplary view for explaining various structural implementations of the FPCB according to some embodiments of the present disclosure;

FIG. 22 is a first exemplary view for explaining a method for manufacturing an FPCB according to some embodiments of the present disclosure;

FIG. 23 is a second exemplary view for explaining the method of manufacturing an FPCB according to some embodiments of the present disclosure;

FIG. 24 is a third exemplary view for explaining a method of manufacturing an FPCB according to some embodiments of the present disclosure;

FIG. 25 is a sixth exemplary view for explaining various structural implementations of the FPCB according to some embodiments of the present disclosure;

FIG. 26 is an exemplary view for explaining various structural implementations of a semiconductor package including the FPCB according to some embodiments of the present disclosure;

FIG. 27 is a table showing first experimental results for the FPCB according to some embodiments of the present disclosure;

FIG. 28 is a table showing second experimental results for the FPCB according to some embodiments of the present disclosure;

FIG. 29 is a graph showing third experimental results for the FPCB according to some embodiments of the present disclosure;

FIG. 30 is a graph showing fourth experimental results for the FPCB according to some embodiments of the present disclosure; and

FIG. 31 is a graph showing fifth experimental results for the FPCB according to some embodiments of the present disclosure.

### DETAILED DESCRIPTION

Embodiments of the present disclosure will now be described in detail with reference to the accompanying drawings. The same reference numerals are used for the same components in the drawings, and redundant descriptions thereof will be omitted.

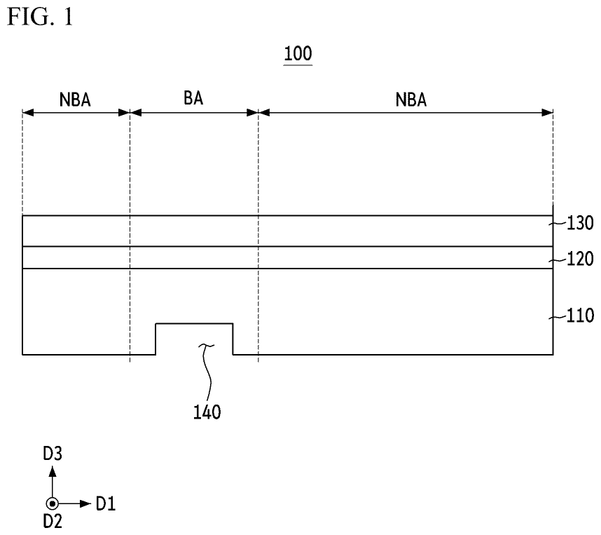

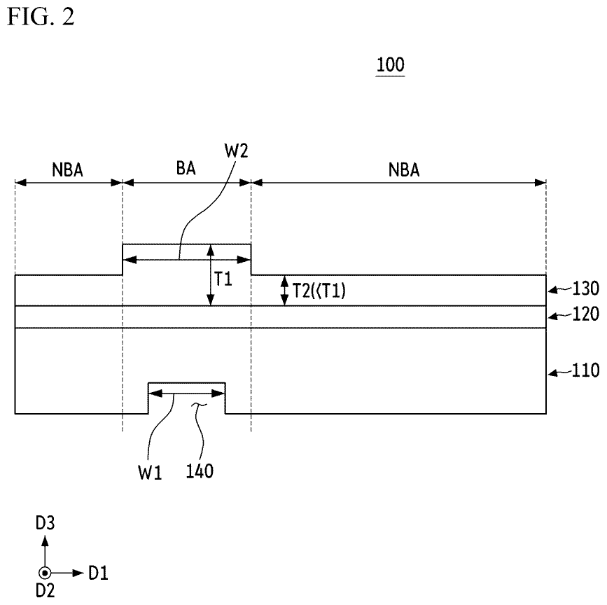

FIG. 1 is a first exemplary view for explaining various structural implementations of a flexible printed circuit board (FPCB) according to some embodiments of the present disclosure. FIG. 2 is a second exemplary view for explaining various structural implementations of the FPCB according to some embodiments of the present disclosure. Referring to FIGS. 1 and 2, an FPCB 100 may include a base film 110, a wiring pattern layer 120, a protective layer 130, and a recess portion 140.

A first direction D1 and a second direction D2 may define a two-dimensional (2D) plane. The first direction D1 may be an X-axis direction, and the second direction D2 may be a Y-axis direction. The first direction D1 may be a left-right direction, and the second direction D2 may be a front-rear direction. Alternatively, the first direction D1 may be the front-rear direction, and the second direction D2 may be the left-right direction. A third direction D3 may define a three-dimensional (3D) structure together with the first and second directions D1 and D2. The third direction D3 is a direction perpendicular to the plane defined by the first and second directions D1 and D2. The third direction D3 may be a Z-axis direction. The third direction D3 may be an up-down direction.

The present disclosure may be applied to the FPCB 100. The FPCB 100 may be installed in an electronic device such as a display or mobile device. For example, the FPCB 100 may be provided in an electronic device as a chip-on-film (COF) on which a semiconductor chip is mounted, but the present disclosure is not limited thereto. That is, the FPCB 100 may also be applicable to other circuit boards having properties such as rigidity or semi-rigidity.

The FPCB 100 may include a bending area BA and an area other than the bending area BA. Areas other than the bending area BA refers to the entire FPCB 100 excluding the bending area BA, and may be defined as non-bending areas NBA. The base film 110, the wiring pattern layer 120, the protective layer 130, and the recess portion 140 which will be described later, may include the bending area BA and the non-bending area NBA, similar to the FPCB 100. The bending area BA and the non-bending area NBA of the base film 110, the wiring pattern layer 120, the protective layer 130, and the recess portion 140 may be provided corresponding to the bending area BA and the non-bending area NBA of the FPCB 100.

The base film 110 may be provided as a core layer having a predetermined thickness. The base film 110 may be provided as a flexible film, but is not limited thereto. The base film 110 may also be provided as a rigid-flexible film or a rigid film.

The base film 110 may include an insulating resin. The base film 110 may include a polymer material having flexibility. For example, the base film 110 may include at least one polymer material selected from among polyimide (PI), polyethylene terephthalate (PET), polyethylene naphthalate (PEN), polycarbonate (PC), epoxy, or glass fiber. The polymer material forming the base film 110 is not limited to this example, and may include any material as long as it ensures insulating performance in the FPCB 100.

The base film 110 may be formed with a width of 25 mm to 250 mm. Here, “width” refers to a dimension in the first direction D1 or the second direction D2. If the width of the base film 110 is less than 25 mm, it may be difficult to form sufficient wiring patterns required to implement a high-resolution display. In addition, if the width of the base film 110 exceeds 250 mm, problems such as sagging or wrinkling of the base film 110 may occur during the manufacturing process.

The base film 110 may be formed to have a thickness of 100 μm or less. Preferably, the base film 110 may be formed to have a thickness of 15 μm to 80 μm. More preferably, the base film 110 may be formed to have a thickness of 15 μm to 40 μm. Here, “thickness” refers to a dimension in the third direction D3. When the base film 110 is formed to have a thickness of 25 μm to 40 μm, the thickness and bezel size of the electronic device including the FPCB 100 may be reduced while securing fluidity of the base film 110 during the manufacturing process. When the base film 110 is formed to have a thickness of 15 μm to 25 μm, the rebound force generated during bending of the FPCB 100 may be reduced.

The base film 110 may include a portion corresponding to the bending area BA and portions corresponding to the non-bending areas NBA. The portion corresponding to the bending area BA may be formed with a length of 30 mm to 250 mm in the first direction D1 or the second direction D2. The portion corresponding to the bending area BA may be formed with a width of 0.1 mm to 30 mm in the first direction D1 or the second direction D2.

Although not illustrated in FIGS. 1 and 2, a seed layer may be provided between the base film 110 and the wiring pattern layer 120. The seed layer may increase the bonding strength between the base film 110 and the wiring pattern layer 120. The seed layer may be provided on the base film 110 as a thin-film conductive layer. The seed layer may include a metal selected from among conductive metals such as nickel (Ni), chromium (Cr), copper (Cu), gold (Au), aluminum (Al), or palladium (Pd), or may be provided as an alloy consisting of two or more metals. The seed layer may be formed on the base film 110 by a physical or chemical method such as deposition, adhesion, or plating.

An under layer may be further provided on the seed layer. The under layer may include the same metal as, or a different metal from, the seed layer. The under layer may have a thickness equivalent to that of the seed layer, but the present disclosure is not limited thereto. That is, the under layer may be thicker or thinner than the seed layer. In some embodiments, only the under layer may be provided between the base film 110 and the wiring pattern layer 120 without the seed layer.

The wiring pattern layer 120 may be formed on the base film 110. The wiring pattern layer 120 may include a conductive material. The wiring pattern layer 120 may include a metallic material. The wiring pattern layer 120 may include a metal selected from among conductive metals such as Ni, Cr, Cu, Au, silver (Ag), platinum (Pt), Al, Pd, titanium (Ti), or tin (Sn), or may be provided as an alloy consisting of two or more metals.

The wiring pattern layer 120 may be formed on the base film 110 by etching, semi-additive process (SAP), additive process, printing, or coating.

Although not illustrated in FIGS. 1 and 2, the wiring pattern layer 120 may include an electrode pattern, an inner lead, and an outer lead. The inner lead may connect the wiring pattern layer 120 to a semiconductor chip. The outer lead may connect the wiring pattern layer 120 to a component inside the electronic device including the FPCB 100. For example, the outer lead may connect the wiring pattern layer 120 to a display panel. The electrode pattern may connect the inner lead and the outer lead.

The wiring pattern layer 120 may be formed to have a thickness of 20 μm or less. Preferably, the wiring pattern layer 120 may be formed to have a thickness of 5 μm to 20 μm. If the wiring pattern layer 120 is formed to have a thickness exceeding 20 μm, it may be difficult to implement fine circuit pitch. The wiring pattern layer 120 may be formed to have a thickness of 5 μm or more. If the wiring pattern layer 120 is formed to have a thickness less than 5 μm, the resistance of the wiring pattern layer 120 may increase.

The protective layer 130 may cover the base film 110 and/or the wiring pattern layer 120. The protective layer 130 may cover the upper surfaces of portions of the base film 110 exposed in areas where the wiring pattern layer 120 is not formed. Alternatively, the protective layer 130 may cover both the upper surface and both side surfaces of the wiring pattern layer 120. Yet alternatively, the protective layer 130 may cover only the upper surface of the wiring pattern layer 120, or only the upper surface and one side surface of the wiring pattern layer 120. The protective layer 130 may protect the wiring pattern layer 120. The protective layer 130 may protect the wiring pattern layer 120. The protective layer 130 may protect the base film 110 or the wiring pattern layer 120 from moisture or foreign substances, and may prevent defects such as short circuits, damage due to oxidation, and delamination.

The protective layer 130 may not cover part of the wiring pattern layer 120. The protective layer 130 may cover the electrode pattern. The protective layer 130 may not cover the inner lead and the outer lead, so that the inner lead and the outer lead may be exposed to the outside.

As will be described later, the FPCB 100 may further include a plating layer. The plating layer may be formed on the wiring pattern layer 120. The protective layer 130 may cover the plating layer formed on the wiring pattern layer 120.

The protective layer 130 may be provided as an insulating resin layer including an insulating polymer material such as solder resist. The protective layer 130 may be formed by various methods such as printing, adhesion, coating, or photolithography.

The thickness of the protective layer 130 may be formed to be uniform from the inside to the ends of the protective layer 130 in the first direction D1 and/or the second direction D2, or to gradually decrease. Alternatively, the thickness of the protective layer 130 may vary depending on where the protective layer 130 is formed. Here, “thickness” refers to a dimension in the third direction D3.

Referring to FIG. 1, the portion of the protective layer 130 corresponding to the bending area BA may be formed to have the same thickness as the portions of the protective layer 130 corresponding to the non-bending areas NBA. Alternatively, as illustrated in FIG. 2, the portion corresponding to the bending area BA may be formed to be thicker than the portion corresponding to the non-bending areas NBA. This will now be described.

The protective layer 130 may be formed to have a first thickness T1 in the bending area BA and a second thickness T2 in the non-bending areas NBA. The first thickness T1 may be different from the second thickness T2. The first thickness T1 may be greater than the second thickness T2. Accordingly, during bending of the FPCB 100, the stress concentrated on the wiring pattern layer 120 in the bending area BA may be suppressed, addressing problems such as cracking in the plating layer, which will be described later.

Alternatively, the first thickness T1 may be less than the second thickness T2. In this case, the thickness of the cured protective layer 130 in the bending area BA may be reduced, securing the bendability of the FPCB 100. However, the present disclosure is not limited to this. Yet alternatively, the first thickness T1 may be equal to the second thickness T2.

The first thickness T1 may be formed to be 5 μm to 35 μm. If the first thickness T1 is less than 5μm, the protective effect against cracking of the wiring pattern layer 120 or plating layer in the bending area BA when bonding the FPCB 100 within an electronic device may be insufficient. If the first thickness T1 exceeds 35 μm, the bendability of the FPCB 100 may be degraded due to an increased level of curing of the protective layer 130, and problems such as delamination or breakage of the protective layer 130 may occur. Such problems may be resolved by forming the first thickness T1 to be 5 μm to 35 μm.

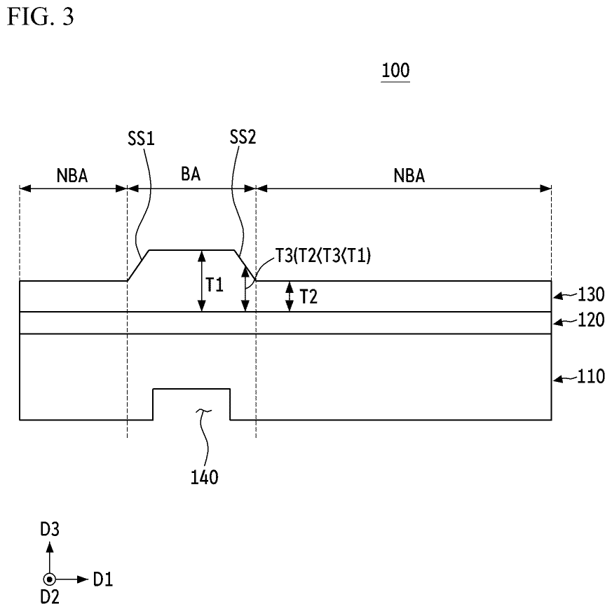

FIG. 3 is a first exemplary view for explaining various structural implementations of the protective layer forming the FPCB according to some embodiments of the present disclosure. Referring to FIG. 3, in the bending area BA, the protective layer 130 may include a portion formed with a first thickness T1. In the non-bending areas NBA, the protective layer 130 may include a portion formed with a second thickness T2. In the bending area BA, the protective layer 130 may further include portions formed with a third thickness T3. The third thickness T3 may be greater than the second thickness T2. The third thickness T3 may be less than the first thickness T1.

A first inclined surface SS1 and a second inclined surface SS2 may connect portions of the protective layer 130 that are located in the bending area BA and the non-bending areas NBA. The first and second inclined surfaces SS1 and SS2 may include the portions of the protective layer 130 formed with the third thickness T3. The first and second inclined surfaces SS1 and SS2 may contact boundary surfaces between the bending area BA and the non-bending areas NBA.

However, the present disclosure is not limited to this, and the first and second inclined surfaces SS1 and SS2 may not contact the boundary surfaces between the bending area BA and the non-bending areas NBA. Alternatively, the first and second inclined surfaces SS1 and SS2 may be formed within the bending area BA, and in the bending area BA, the protective layer 130 may include a portion formed with the first thickness T1, a portion formed with the second thickness T2, and a portion formed with the third thickness T3. Yet alternatively, the first and second inclined surfaces SS1 and SS2 may be formed to include the boundary surfaces between the bending area BA and the non-bending areas NBA, and in the bending area BA, the protective layer 130 may include a portion formed with the first thickness T1 and a portion formed with the third thickness T3. In the non-bending areas NBA, the protective layer 130 may include a portion formed with the second thickness T2 and a portion formed with a fourth thickness T4. The fourth thickness T4 may be greater than the second thickness T2. The fourth thickness T4 may be less than the third thickness T3.

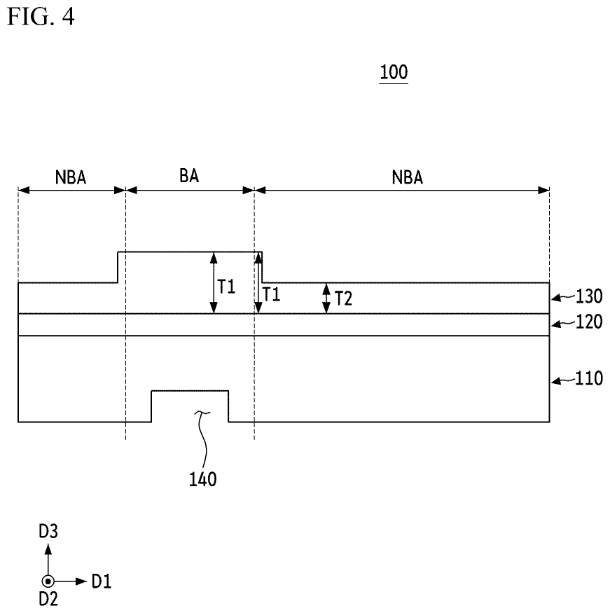

FIG. 4 is a second exemplary view for explaining various structural implementations of the protective layer forming the FPCB according to some embodiments of the present disclosure. Referring to FIG. 4, in the non-bending areas NBA, the protective layer 130 may include a portion formed with a first thickness T1 and a portion formed with a second thickness T2. Among the portions of the protective layer 130 in the non-bending areas NBA, the portion formed with the first thickness T1 may be formed to have the same thickness as the portion of the protective layer 130 in the bending area BA. The portion of the protective layer 130 formed with the first thickness T1 in the non-bending areas NBA may be adjacent to the bending area BA.

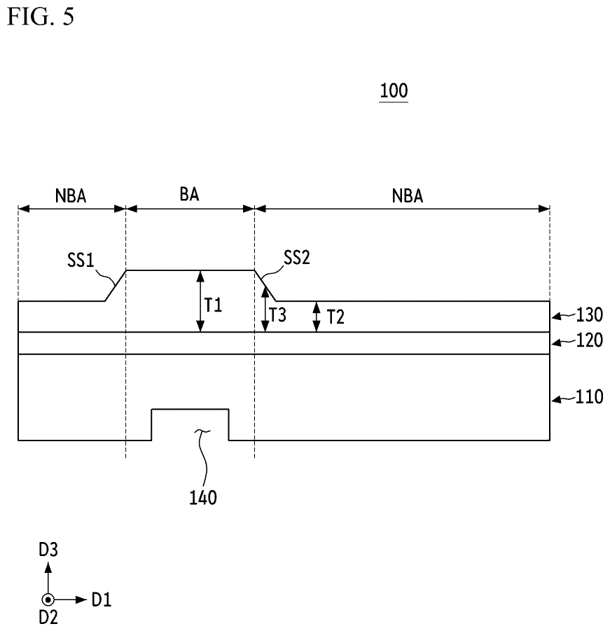

FIG. 5 is a third exemplary view for explaining various structural implementations of the protective layer forming the FPCB according to some embodiments of the present disclosure. Referring to FIG. 5, in the bending area BA, the protective layer 130 may include a portion formed with the first thickness T1. In the non-bending areas NBA, the protective layer 130 may include portions formed with the second thickness T2. In the non-bending areas NBA, the protective layer 130 may further include portions formed with the third thickness T3.

The first and second inclined surfaces SS1 and SS2 may include the portions of the protective layer 130 formed with the third thickness T3. The first and second inclined surfaces SS1 and SS2 may contact the boundary surfaces between the bending area BA and the non-bending areas NBA.

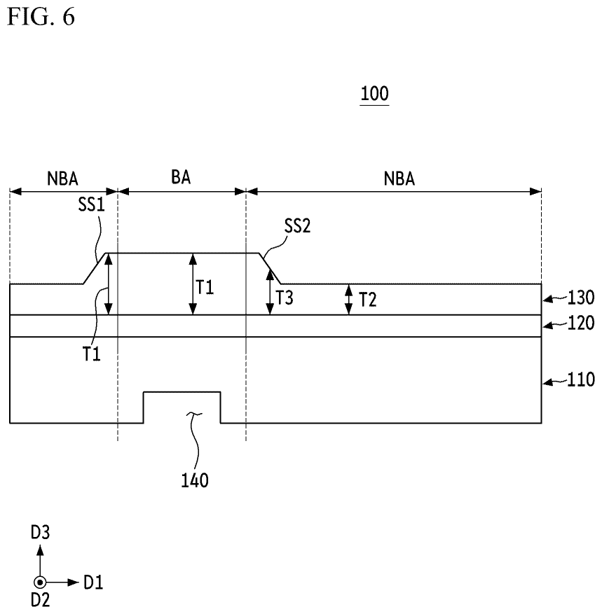

FIG. 6 is a fourth exemplary view for explaining various structural implementations of the protective layer forming the FPCB according to some embodiments of the present disclosure. Referring to FIG. 6, the first and second inclined surfaces SS1 and SS2 may be formed in the non-bending areas NBA. In the non-bending areas NBA, the protective layer 130 may include portions formed with the first thickness T1, portions formed with the second thickness T2, and portions formed with the third thickness T3. Among the portions of the protective layer 130 in the non-bending areas NBA, the portions formed with the first thickness T1 may be formed to have the same thickness as the portion of the protective layer 130 in the bending area BA.

The protective layer 130 may be integrally formed. When the protective layer 130 is integrally formed, the stress caused by tension during bending of the FPCB 100 may be distributed throughout the protective layer 130, thereby improving reliability and preventing delamination of the protective layer 130 from the FPCB 100.

Alternatively, the protective layer 130 may be formed with two or more insulating layers. The protective layer 130 may include a first insulating layer 131 that covers the portion of the base film 110 or wiring pattern layer 120 in the bending area BA, and second insulating layers that cover the first insulating layer 131 and the base film 110 or wiring pattern layer 120 in the non-bending areas NBA.

Yet alternatively, the protective layer 130 may include a plurality of first insulating layers 131 that cover the base film 110 or the wiring pattern layer 120 in part of the bending area BA and parts of the non-bending areas NBA, and second insulating layers that cover the base film 110 or the wiring pattern layer 120 in the remaining non-bending areas NBA.

Through this, it is possible to locally control the thickness of the protective layer 130 in areas of the FPCB 100 where stress distribution is required, which is advantageous for miniaturizing electronic devices. In addition, it is possible to prevent the formation of a plating layer, which will be described later, in areas where stress is concentrated in the FPCB 100, thereby solving problems such as cracking of the wiring pattern layer 120 or the plating layer in the bending area BA during bending of the FPCB 100.

Meanwhile, the present disclosure is not limited to this, and one or more first insulating layer 131 and/or one or more second insulating layers 132 may be formed in various regions.

Further, as will be described later, the protective layer 130 may be formed integrally in the final product by forming the first insulating layer 131 and then removing it before formation of the second insulating layers 132.

Referring again to FIG. 1, the recess portion 140 may be formed as one or more indentations on one or both surfaces of the base film 110. The recess portion 140 may be formed in a region of the base film 110 on which the wiring pattern layer 120 is not formed. When the wiring pattern layer 120 is formed on one surface of the base film 110, the recess portion 140 may be formed on the opposite surface of the base film 110. Alternatively, the recess portion 140 may be formed on the surface of the base film 110 where the wiring pattern layer 120 is formed.

The recess portion 140 may be provided in the bending area BA, and the thickness of the base film 110 in the bending area BA may be reduced by the recess portion 140. Through this, the initial thickness of the base film 110 may be maintained in the non-bending areas NBA, thereby ensuring process flow, and as the stress accumulated in the base film 110 in the bending area BA during bending of the FPCB 100 is reduced, the resulting rebound force may be alleviated.

Hereinafter, the indentations forming the recess portion 140 will be defined as recesses, and various embodiments of the recess portion 140 including the recesses and the effect of rebound force improvement will be described in detail.

The width and thickness of the recess portion 140 may vary. Here, “width” refers to a dimension in the first direction D1 or the second direction D2, and “thickness” refers to a dimension in the third direction D3. The width and/or thickness of the recess portion 140 may be determined in consideration of the width and/or thickness of the portion of the base film 110 corresponding to the recess portion 140, the structure of the recesses forming the recess portion 140, or the width and/or thickness of the protective layer 130.

The recess portion 140 may be provided to have a width equal to that of the bending area BA. Here, “width” refers to a dimension in the first direction D1 or the second direction D2. However, the present disclosure is not limited to this, and alternatively, the recess portion 140 may have a smaller width than the bending area BA.

The recesses of the recess portion 140 may be provided with a first width W1. The first width W1 may be 10μm or more in the first direction D1 or the second direction D2. In this case, the first width W1 may be defined as the largest width of the recess portion 140 at the same level as the surface of the base film 110 among its widths in the third direction D3. If an intermediate or smallest width of the recess portion 140 on the inner surface of the base film 110 is used as the first width W1, the recesses may overlap with one another or fail to achieve a required processing depth RT. When there are multiple recesses, the spacing between the recesses may be formed to be 300 μm or less. The bending area BA of the FPCB 100 may be provided with a second width W2. The first width W1 may be equal to or smaller than the second width W2.

The recesses of the recess portion 140 may be formed with a processing depth RT that is smaller than the thickness of the base film 110. Preferably, the recesses of the recess portion 140 may be formed with a processing depth RT of 10% to 80% relative to the thickness of the base film 110. Thus, even if the first thickness T1 of the protective layer 130 is greater than the second thickness T2 of the protective layer 130 to prevent cracking of the wiring pattern layer 120 in the bending area BA, or even if the base film 110 is provided with a predetermined thickness for process fluidity, the total thickness of the bending area BA of the FPCB 100 may be reduced to the level of the processing depth RT of the recess portion 140, thereby reducing rebound force during bending.

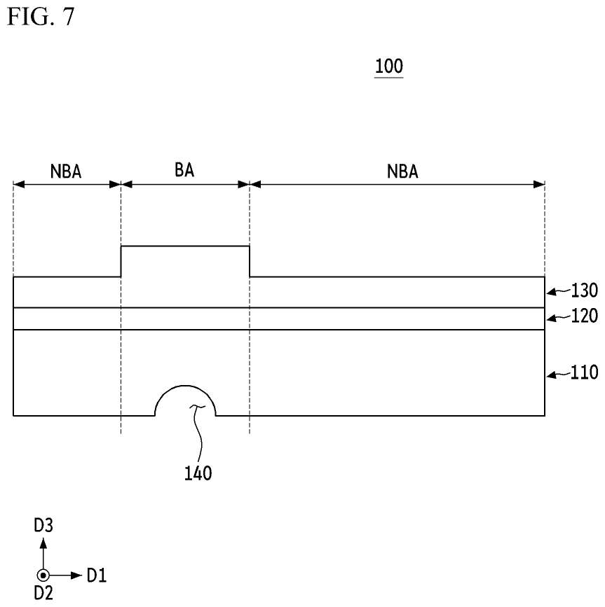

The recess portion 140 may be provided in a polygonal shape, such as triangular or quadrangular, in a cross-section view taken along the third direction D3, but the present disclosure is not limited thereto. Alternatively, the recess portion 140 may be provided in a semicircular or semielliptical shape in the third direction D3. FIG. 7 is a first exemplary view for explaining various structural implementations of the recess portion forming the FPCB according to some embodiments of the present disclosure. Referring to FIG. 7, the recess portion 140 may be provided as a semicircular indentation. The recess portion 140 may be formed with an inner surface that is flat, or may be formed in a rounded shape, a wavy shape, a crown shape, or the like.

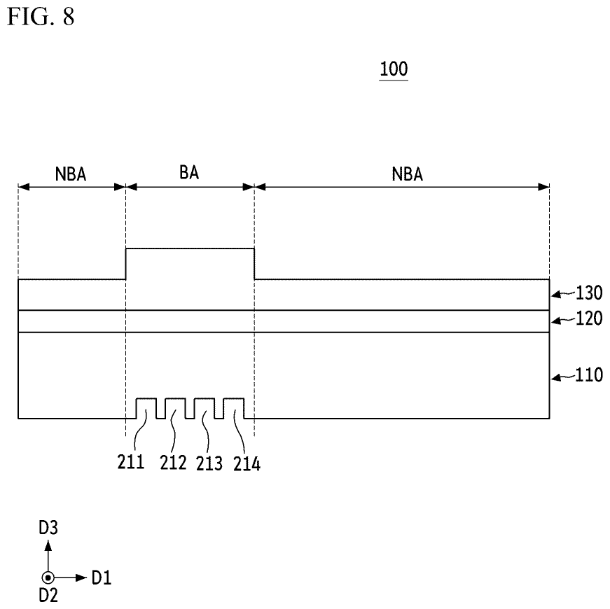

The recess portion 140 may be provided as a single recess, but the present disclosure is not limited thereto. Alternatively, the recess portion 140 may be provided as a plurality of recesses. The plurality of recesses may be formed at regular intervals within the bending area BA. FIG. 8 is a second exemplary view for explaining various structural implementations of the recess portion forming the FPCB according to some embodiments of the present disclosure. Referring to FIG. 8, the plurality of recesses may include a first recess 211, a second recess 212, a third recess 213, and a fourth recess 214. The first through fourth recesses 211 through 214 may be spaced apart from one another at regular intervals. The FPCB 100 may uniformly disperse the stress applied to the bending area BA during bending through the first through fourth recesses 211 through 214.

The first through fourth recesses 211 through 214 may be formed with the same width, but the present disclosure is not limited thereto. Alternatively, at least one of the first through fourth recesses 211 through 214 may be formed with a different width from the other recesses.

The first through fourth recesses 211 through 214 may be formed with the same processing depth, but the present disclosure is not limited thereto. Alternatively, at least one of the first through fourth recesses 211 through 214 may be formed with a different processing depth from the other recesses.

The first through fourth recesses 211 through 214 may be formed in the same shape, but the present disclosure is not limited thereto. Alternatively, at least one of the first through fourth recesses 211 through 214 may be formed in a different shape from the other recesses.

The plurality of recesses may be formed at irregular intervals within the bending area BA. If the bending area BA is divided into a plurality of zones, the plurality of recesses may be formed only in some of the zones of the bending area BA. Alternatively, different numbers of recesses may be provided by zone. The FPCB 100 may efficiently disperse stress by arranging a plurality of recesses in portions of the bending area BA having a large radius of curvature or concentrated stress during bending.

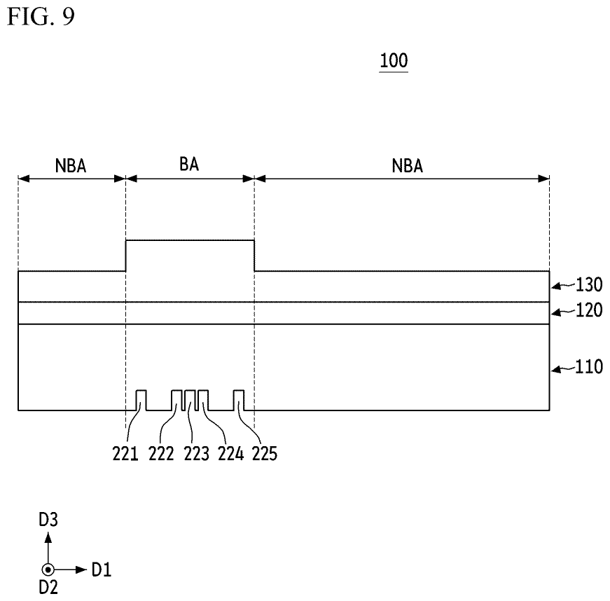

FIG. 9 is a third exemplary view for explaining various structural implementations of the recess portion forming the FPCB according to some embodiments of the present disclosure. Referring to FIG. 9, the plurality of recesses may include a first recess 221, a second recess 222, a third recess 223, a fourth recess 224, and a fifth recess 225. The second through fourth recesses 224 may be formed in a center zone within the bending area BA. The first and fifth recesses 221 through 225 may be formed in edge zones within the bending area BA. The first through fifth recesses 221 through 225 may be formed only in the center zone and edge zones, and not in middle zones.

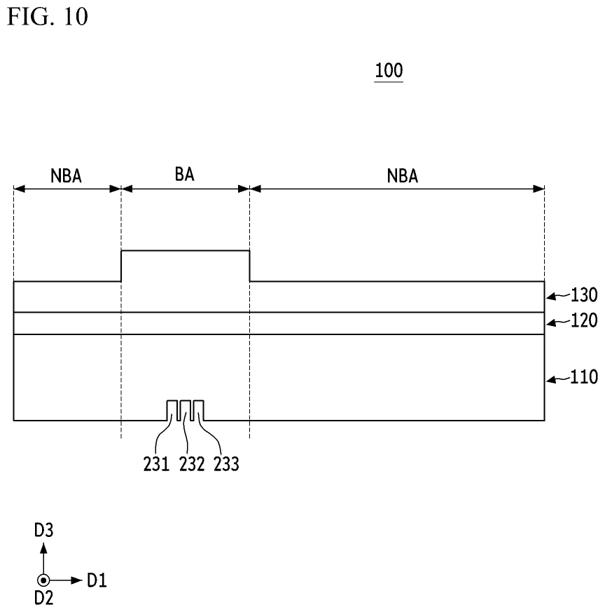

FIG. 10 is a fourth exemplary view for explaining various structural implementations of the recess portion forming the FPCB according to some embodiments of the present disclosure. Referring to FIG. 10, the plurality of recesses may include a first recess 231, a second recess 232, and a third recess 233. The first through third recesses 231 through 233 may be formed in a center zone within the bending area BA. The first through third recesses 231 through 233 may be formed only in the center zone, and not in the middle zones and edge zones.

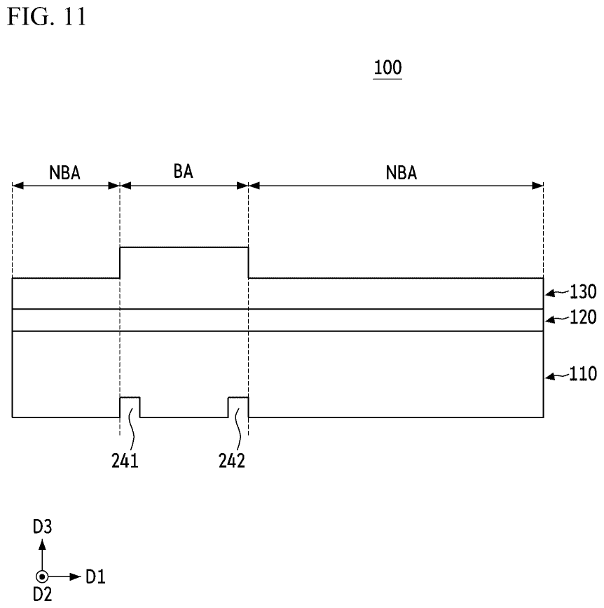

FIG. 11 is a fifth exemplary view for explaining various structural implementations of the recess portion forming the FPCB according to some embodiments of the present disclosure. Referring to FIG. 11, the plurality of recesses may include a first recess 241 and a second recess 242. The first and second recesses 241 and 242 may be formed in an edge zone within the bending area BA. The first and second recesses 241 and 242 may be formed only in the edge zone, and not in the center zones and middle zones.

Referring to FIGS. 9 through 11, the plurality of recesses may be formed with the same width, but the present disclosure is not limited thereto. Alternatively, at least one of the plurality of recesses may be formed with a different width from the other recesses. Yet alternatively, the plurality of recesses may all be formed with different widths.

In addition, the plurality of recesses may be formed with the same thickness, but the present disclosure is not limited thereto. Alternatively, at least one of the plurality of recesses may be formed with a different thickness from the other recesses. Alternatively, the plurality of recesses may all be formed with different thicknesses.

In addition, the plurality of recesses may be formed in the same shape, but the present disclosure is not limited thereto. Alternatively, at least one of the plurality of recesses may be formed in a different shape from the other recesses.

The width of the recess portion 140 may vary relative to the thickness of the recess portion 140. The width of the recess portion 140 may be greater than the thickness of the recess portion 140, but the present disclosure is not limited thereto. Alternatively, the width of the recess portion 140 may be equal to the thickness of the recess portion 140. Yet alternatively, the width of the recess portion 140 may be less than the thickness of the recess portion 140.

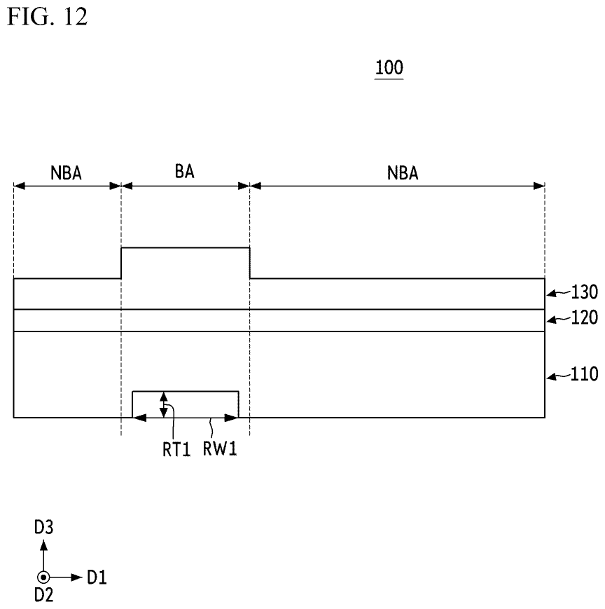

The width and thickness of the recess portion 140 may vary depending on the number of recesses. FIG. 12 is a sixth exemplary view for explaining various structural implementations of the recess portion forming the FPCB according to some embodiments of the present disclosure. The recess portion 140 may include a single recess. The single recess may have a width greater than its thickness. Referring to FIG. 12, the recess portion 140 may include a first recess 251. A width RW1 of the first recess 251 may be greater than a thickness RT1 of the first recess 251, but the present disclosure is not limited thereto. Alternatively, the width RW1 of the first recess 251 may be equal to the thickness RT1 of the first recess 251.

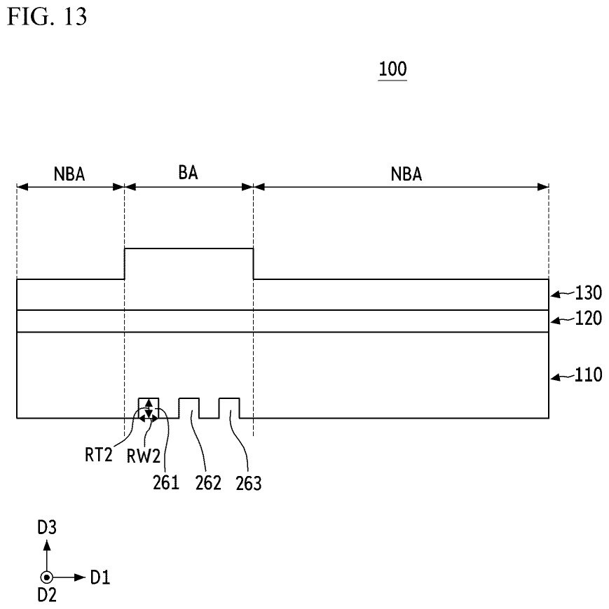

FIG. 13 is a seventh exemplary view for explaining various structural implementations of the recess portion forming the FPCB according to some embodiments of the present disclosure. The recess portion 140 may include a plurality of recesses. The plurality of recesses may have a width smaller than their thickness. Alternatively, the plurality of recesses may have a width equal to their thickness. Referring to FIG. 13, the recess portion 140 may include a first recess 261, a second recess 262, and a third recess 263. A width RW2 of the first through third recesses 261 through 263 may be smaller than a thickness RT2 of the first through third recesses 261 through 263, but the present disclosure is not limited thereto. Alternatively, the width RW2 of the first through third recesses 261 through 263 may be equal to the thickness RT2 of the first through third recesses 261 through 263. Yet alternatively, the width RW2 of the first through third recesses 261 through 263 may be greater than the thickness RT2 of the first through third recesses 261 through 263.

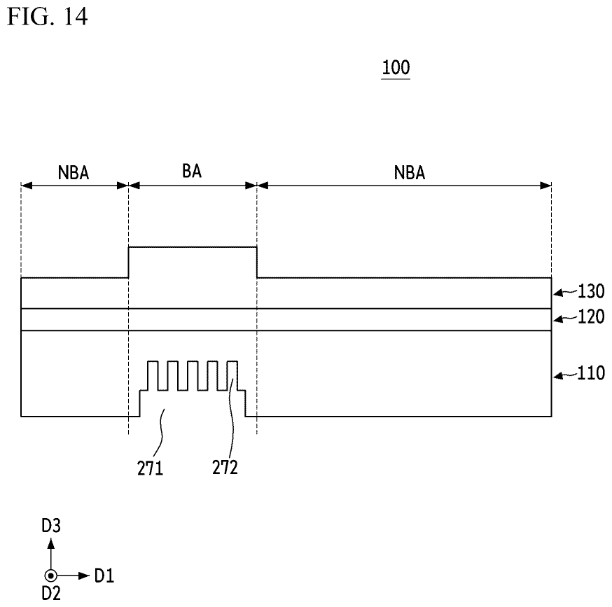

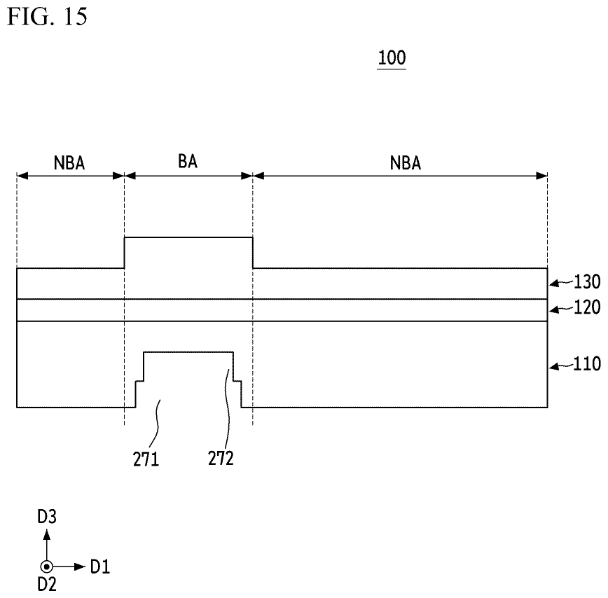

The recess portion 140 may be formed in a single-layer structure, but the present disclosure is not limited thereto. Alternatively, the recess portion 140 may be formed in a multi-layer structure. FIG. 14 is an eighth exemplary view for explaining various structural implementations of the recess portion forming the FPCB according to some embodiments of the present disclosure. FIG. 15 is a ninth exemplary view for explaining various structural implementations of the recess portion forming the FPCB according to some embodiments of the present disclosure.

Referring to FIGS. 14 and 15, the recess portion 140 may include a first recess layer 271 and a second recess layer 272. The first recess layer 271 may include a single recess. The second recess layer 272 may be positioned at a level higher in the third direction D3 than the first recess layer 271. The second recess layer 272 may include a plurality of recesses, but the present disclosure is not limited thereto. Alternatively, the second recess layer 272 may include a single recess.

The second recess layer 272 may be provided with the same width as the first recess layer 271, but the present disclosure is not limited thereto. Alternatively, the second recess layer 272 may be provided with a different width from the first recess layer 271. The second recess layer 272 may be provided with a smaller width than the first recess layer 271. The recess portion 140 may be provided to have a stepwise structure. The recess portion 140 may be formed in a stair-step structure.

The second recess layer 272 may be provided with the same thickness as the first recess layer 271, but the present disclosure is not limited thereto. Alternatively, the second recess layer 272 may be provided with a different thickness from the first recess layer 271. In addition, the second recess layer 272 may be provided in the same shape as the first recess layer 271, but alternatively, the second recess layer 272 may be provided in a different shape from the first recess layer 271.

The recess portion 140 may be formed along a lengthwise direction of the base film 110. Here, the lengthwise direction may refer to the first direction D1, but the present disclosure is not limited thereto. Alternatively, the lengthwise direction may refer to the second direction D2.

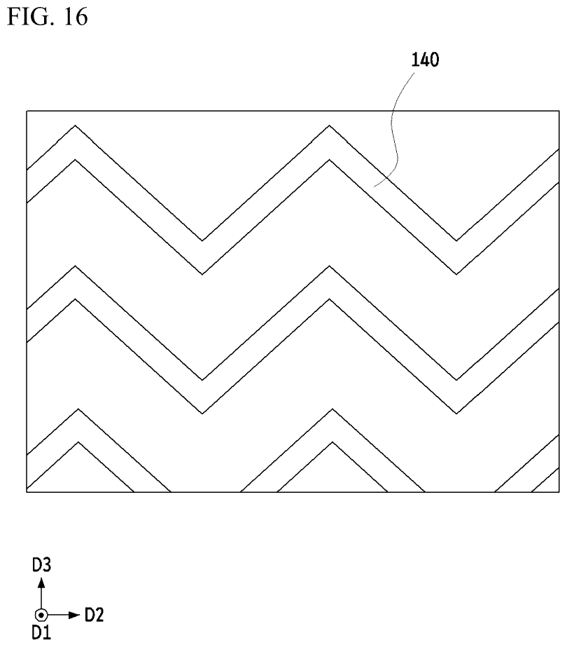

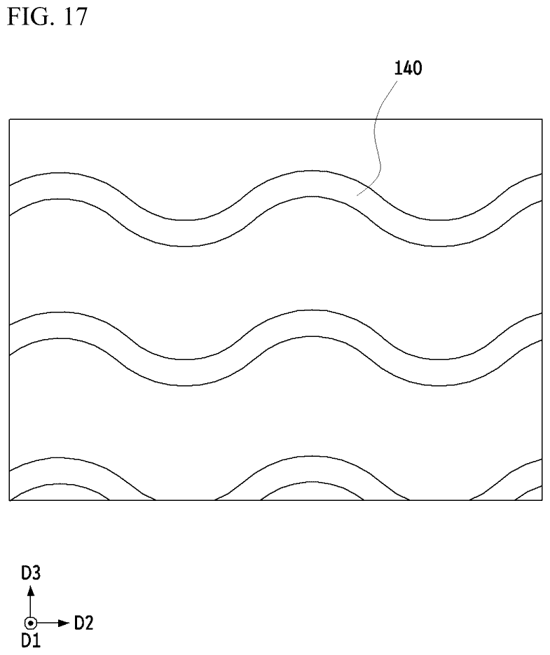

The recess portion 140 may be formed in a continuous line type. Referring to FIGS. 16 and 17, the recess portion 140 may be formed continuously in the first direction D1 or the second direction D2 from one end to the other end of the base film 110. For example, the recess portion 140 may be provided in an I-shape, S-shape, W-shape, or zigzag shape. FIG. 16 is a tenth exemplary view for explaining various structural implementations of the recess portion forming the FPCB according to some embodiments of the present disclosure. FIG. 17 is an eleventh exemplary view for explaining various structural implementations of the recess portion forming the FPCB according to some embodiments of the present disclosure.

Alternatively, a plurality of line-shaped recesses may be formed discontinuously at predetermined intervals in the first direction D1 or the second direction D2 from one end to the other end of the base film 110, but the present disclosure is not limited thereto.

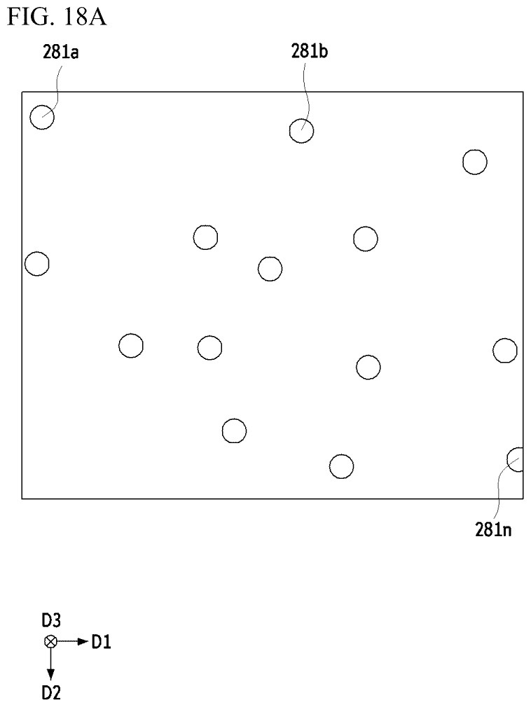

Referring to FIGS. 18A through 18C, the recess portion 140 may be provided as dot-type recesses. The recess portion 140 may include a plurality of recesses 281a, 281b, . . . , 281n, and the recesses 281a, 281b, . . . , 281n may be provided in various shapes such as a circle, ellipse, donut, triangle, quadrangle, or polygon. As illustrated in FIGS. 18A through 18C, the recesses 281a, 281b, . . . , 281n may be arranged in various patterns. In addition, as illustrated in FIGS. 18A through 18C, the recesses 281a, 281b, . . . , 281n may also be provided in various sizes. However, the present disclosure is not limited to this, and the recesses 281a, 281b, . . . , 281n may also be provided in an undefined shape composed of different curves or straight lines in the first and second directions D1 and D2, for example, in a shape such as ⊂⊃. In addition, the recesses 281a, 281b, . . . , 281n may be formed in different shapes from one another. FIG. 18A is a twelfth exemplary view for explaining various structural implementations of the recess portion forming the FPCB according to some embodiments of the present disclosure. FIG. 18B is a thirteenth exemplary view for explaining various structural implementations of the recess portion forming the FPCB according to some embodiments of the present disclosure. FIG. 18C is a fourteenth exemplary view for explaining various structural implementations of the recess portion forming the FPCB according to some embodiments of the present disclosure.

Unlike line-shaped recesses, the recesses 281a, 281b, . . . , 281n, which are dot-type recesses, may not be formed as extended shapes but rather as individual shapes spaced apart from one another at predetermined intervals. For example, the recesses 281a, 281b, . . . , 281n may be regularly arranged with one another along a common imaginary axis. Alternatively, the recesses 281a, 281b, . . . , 281n may be irregularly arranged along different imaginary axes.

When the recess portion 140 is provided as dot-type recesses, the recesses may be formed with a width of 10 μm to 50 μm in the first direction D1 or the second direction D2, and the width of the recesses may be determined in consideration of a processing depth RT, which will be described later in further detail.

The processing depth RT of the recesses of the recess portion 140 may be formed to be 10% to 80% of the thickness of the base film 110. For example, when the base film 110 is 40 μm thick, the recesses may be formed with a depth in the range of 4 μm to 32 μm. In another example, when the base film 110 is 25 μm thick, the processing depth RT may be formed in the range of 2.5 μm to 20 μm. If the processing depth RT of the recesses is less than 10% of the thickness of the base film 110, the stress-relief effect of the recesses may be insufficient. Conversely, if the processing depth RT of the recesses exceeds 80%, process flow or product durability may deteriorate.

In addition, an average spacing between adjacent recesses may be set in the range of 30 μm to 300 μm, and preferably in the range of 50 μm to 250 μm. Furthermore, the average pitch of the recesses may be set in the range of 40 μm to 350 μm. Here, “pitch” refers to the distance between the center of the first width W1 of a first recess and the center of the first width W1 of an adjacent second recess, and “average pitch” refers to a mean value of the pitches calculated from ten or more recesses formed in a unit area (mm²).

The recess portion 140 may selectively adopt the aforementioned various shapes in consideration of the overall size of the FPCB 100, the size of the bending area, the width and/or thickness of the base film 110, the degree of bending of the FPCB 100 installed in the electronic device, or the width and/or thickness of the protective layer 130, so as to reduce rebound force of the FPCB 100. By designing the recess portion 140 in consideration of these factors, the FPCB 100 may not only alleviate rebound force but also secure bendability, thereby reducing the area occupied by the FPCB 100 within the electronic device.

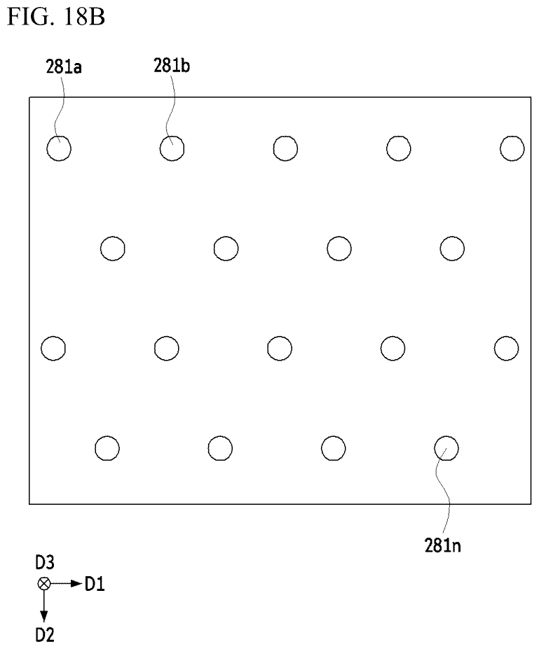

FIG. 19 is a third exemplary view for explaining the structure of the FPCB according to some embodiments of the present disclosure. Referring to FIG. 19, the FPCB 100 may include a base film 110, a wiring pattern layer 120, a protective layer 130, a recess portion 140, and a plating portion 150. The FPCB 100 of FIG. 19 may further include the plating portion 150 compared to the FPCB 100 of FIG. 1.

The plating portion 150 may be formed on the wiring pattern layer 120. The plating portion 150 may cover the upper surface and both side surfaces of the wiring pattern layer 120, but the present disclosure is not limited thereto. Alternatively, the plating portion 150 may cover the upper surface and one side surface of the wiring pattern layer 120. Yet alternatively, the plating portion 150 may cover only the upper surface of the wiring pattern layer 120. The plating portion 150 may be formed to have a thickness of 3 μm or less.

The plating portion 150 may include the same metal as the wiring pattern layer 120. Alternatively, the wiring pattern layer 120 and the plating portion 150 may include different metals. The wiring pattern layer 120 may include Cu, and the plating portion 150 may include Sn. A substitution/diffusion reaction may occur between Cu and Sn. Part of the plating portions 150 in contact with the wiring pattern layer 120 may have a high Cu content. Part of the plating portions 150 not in contact with the wiring pattern layer 120 may have a low Cu content. The Cu content of the plating portion 150 may decrease in a direction away from the part of the plating portion 150 in contact with the wiring pattern layer 120. Surface part of the plating portions 150 may consist of pure Sn.

The plating portion 150 may be entirely formed on the wiring pattern layer 120, but the present disclosure is not limited thereto. Alternatively, the plating portion 150 may be partially formed on the wiring pattern layer 120. When the plating portion 150 is entirely formed on the wiring pattern layer 120, it may be formed on a portion of the wiring pattern layer 120 located in a bending area BA and portions of the wiring pattern layer 120 located in non-bending areas NBA. When formed in this manner, the plating portion 150 may be effective for productivity and manufacturing cost reduction.

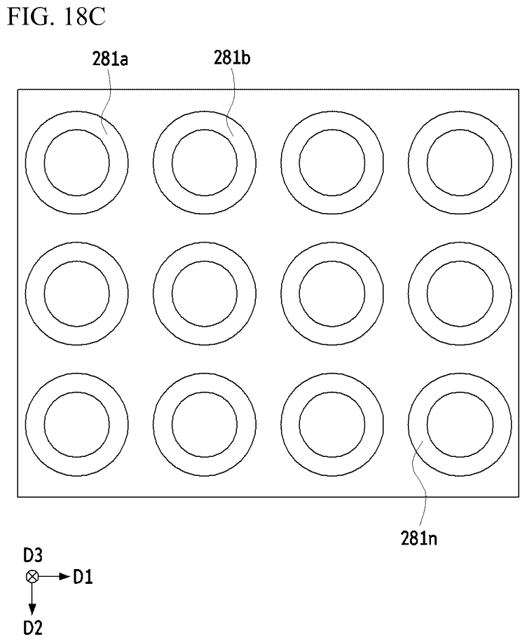

FIG. 20 is a fourth exemplary view for explaining the structure of the FPCB according to some embodiments of the present disclosure. Referring to FIG. 20, when the plating portion 150 is partially formed on the wiring pattern layer 120, it may be formed only on the portions of the wiring pattern layer 120 located in the non-bending areas NBA, and not on the portion of the wiring pattern layer 120 located in the bending area BA. When the plating portion 150 is formed in this manner, cracks in the thin plating portion 150 caused by stress during bending of the FPCB 100 may be prevented.

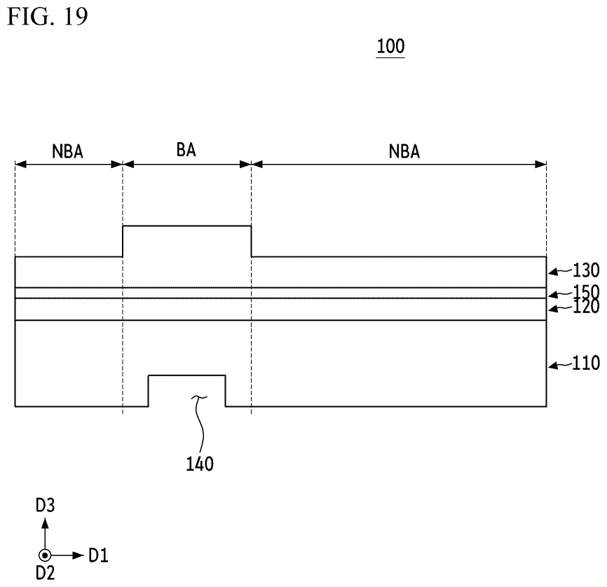

The plating portion 150 may include a single plating layer, but the present disclosure is not limited thereto. Alternatively, the plating portion 150 may include a plurality of plating layers. FIG. 21 is a fifth exemplary view for explaining the structure of the FPCB according to some embodiments of the present disclosure. Referring to FIG. 21, the plating portion 150 may include a first plating layer 310 and a second plating layer 320.

The first plating layer 310 may be formed on the wiring pattern layer 120. The first plating layer 310 may cover the upper surface of the wiring pattern layer 120. The first plating layer 310 may be provided between the wiring pattern layer 120 and the protective layer 130. The first plating layer 310 may be formed to overlap the protective layer 130 in the third direction D3. The first plating layer 310 may partially include an open area.

The second plating layer 320 may be formed on the wiring pattern layer 120 and the first plating layer 310. The second plating layer 320 may cover a portion of the first plating layer 310 not covered by the protective layer 130. For example, the second plating layer 320 may cover the outermost upper surface and side surface of the first plating layer 310. The second plating layer 320 may cover a portion of the wiring pattern layer 120 not covered by the first plating layer 310. For example, the second plating layer 320 may cover the outermost side surface of the wiring pattern layer 120. The second plating layer 320 may be formed in contact with a side surface of the protective layer 130. The second plating layer 320 may be formed to be thicker than the first plating layer 310.

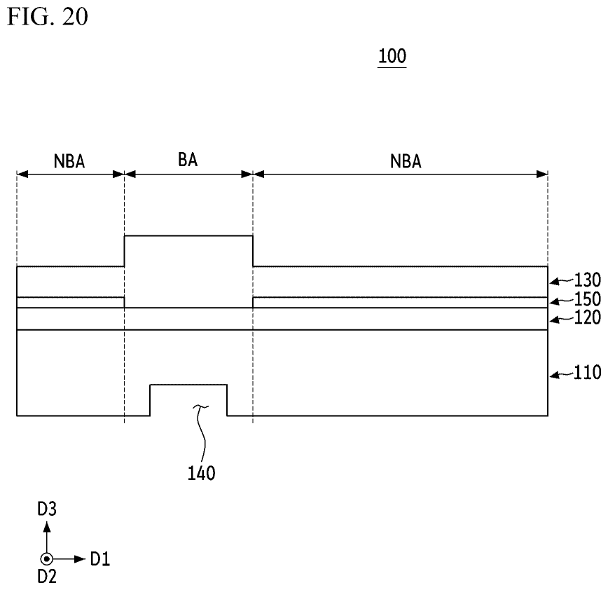

Methods for manufacturing the FPCB 100 will hereinafter be described. FIG. 22 is a first exemplary view for explaining a method for manufacturing an FPCB according to some embodiments of the present disclosure. An FPCB 100 of FIG. 22 may include a base film 110, a wiring pattern layer 120, a protective layer 130, a recess portion 140, and a plating portion 150. The protective layer 130 may include a first insulating layer 131 and a second insulating layer 132. The plating portion 150 may include a first plating layer 310 and a second plating layer 320. The FPCB 100 of FIG. 22 may be a final product produced by the method to be described below.

First, the wiring pattern layer 120 is formed on a surface of the base film 110.

Thereafter, the first insulating layer 131 is partially formed on the wiring pattern layer 120. The first insulating layer 131 may be formed on an upper portion of the wiring pattern layer 120 that corresponds to a bending area BA.

Thereafter, the first plating layer 310 is formed on portions of the wiring pattern layer 120 excluding the portion where the first insulating layer 131 is formed. The first plating layer 310 may be formed on portions of the upper surface of the wiring pattern layer 120 corresponding to non-bending areas NBA, but the present disclosure is not limited thereto. That is, the first plating layer 310 may also be partially formed within the bending area BA.

Thereafter, the second insulating layer 132 is formed to cover the first plating layer 310 and the first insulating layer 131. The second insulating layer 132 may cover portions of the base film 110 where the wiring pattern layer 120 is not formed. The second insulating layer 132 may not cover a portion of the first plating layer 310. The second insulating layer 132 may not cover an outermost side portion of the first plating layer 310.

Thereafter, the second plating layer 320 is formed to cover the portion of the first plating layer 310 not covered by the second insulating layer 132. The second plating layer 320 may cover the upper surface and side surface of the first plating layer 310. The second plating layer 320 may cover a side surface of the wiring pattern layer 120. The second plating layer 320 may be in contact with the upper surface of the base film 110 or a side surface of the second insulating layer 132. The second plating layer 320 may be formed to be thicker than the first plating layer 310.

Thereafter, the recess portion 140 is formed on the lower surface of the base film 110. The recess portion 140 may be formed using various methods such as laser processing, etching, or cutting. The recess portion 140 may be formed through one or more processing steps. The recess portion 140 may be formed in a portion of the base film 110 that corresponds to the bending area BA.

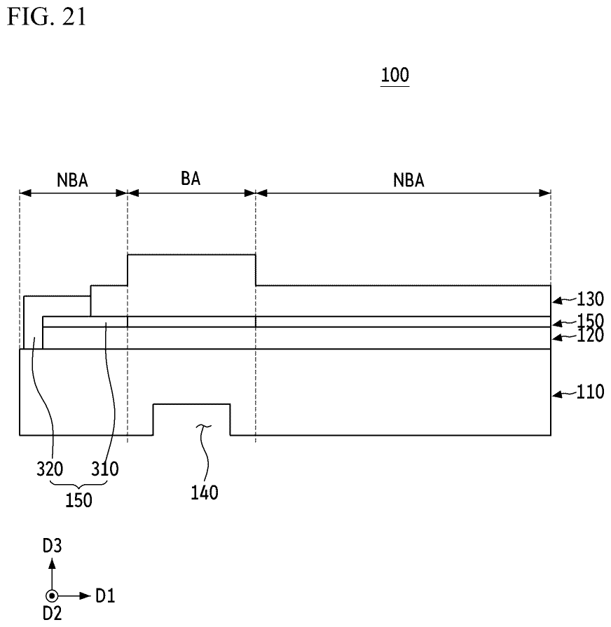

The first insulating layer 131 may be formed on the wiring pattern layer 120, but the present disclosure is not limited thereto. That is, the first insulating layer 131 may also be formed on the first plating layer 310. FIG. 23 is a second exemplary view for explaining the method for manufacturing an FPCB according to some embodiments of the present disclosure. An FPCB 100 of FIG. 23 may include a base film 110, a wiring pattern layer 120, a protective layer 130, a recess portion 140, and a plating portion 150. The protective layer 130 may include a first insulating layer 131 and a second insulating layer 132. The plating portion 150 may include a first plating layer 310 and a second plating layer 320. The FPCB 100 of FIG. 23 may be a final product produced by the method to be described below.

First, the wiring pattern layer 120 is formed on a surface of the base film 110.

Thereafter, the first plating layer 310 is formed on the wiring pattern layer 120.

Thereafter, the first insulating layer 131 is partially formed on the first plating layer 310. The first insulating layer 131 may be formed on an upper portion of the first plating layer 310 that corresponds to a bending area BA.

Thereafter, the second insulating layer 132 is formed to cover the first plating layer 310 and the first insulating layer 131. The second insulating layer 132 may cover portions of the base film 110 where the wiring pattern layer 120 is not formed. The second insulating layer 132 may not cover a portion of the first plating layer 310. The second insulating layer 132 may not cover an outermost side portion of the first plating layer 310.

Thereafter, the second plating layer 320 is formed to cover the portion of the first plating layer 310 not covered by the second insulating layer 132. The second plating layer 320 may cover the upper surface and side surface of the first plating layer 310. The second plating layer 320 may cover a side surface of the wiring pattern layer 120. The second plating layer 320 may be in contact with the upper surface of the base film 110 and a side surface of the second insulating layer 132.

Thereafter, the recess portion 140 is formed on the lower surface of the base film 110. The recess portion 140 may be formed at a location corresponding to the first insulating layer 131. The recess portion 140 may be formed in a portion of the base film 110 that corresponds to the bending area BA.

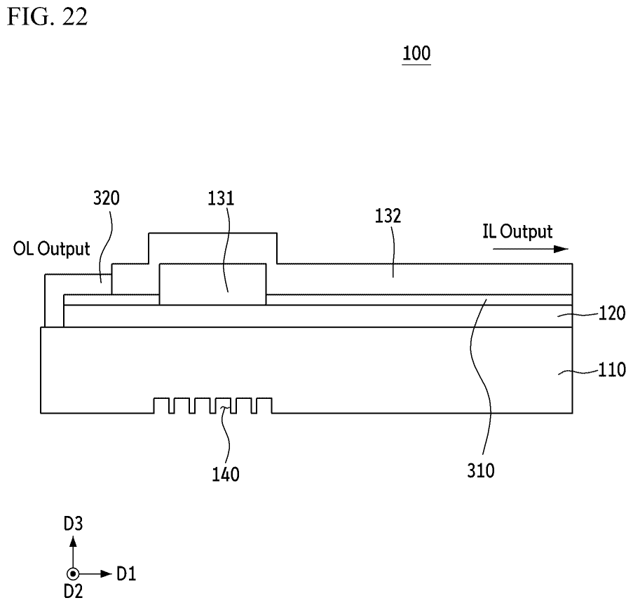

The plating portion 150 may include only the first plating layer 310 and may not include the second plating layer 320. FIG. 24 is a third exemplary view for explaining a method for manufacturing an FPCB according to some embodiments of the present disclosure. An FPCB 100 of FIG. 24 may include a base film 110, a wiring pattern layer 120, a protective layer 130, a recess portion 140, and a plating portion 150. The protective layer 130 may include a first insulating layer 131 and a second insulating layer 132. The FPCB 100 of FIG. 24 may be a final product produced by the method to be described below.

First, the wiring pattern layer 120 is formed on a surface of the base film 110.

Thereafter, the first insulating layer 131 is partially formed on the wiring pattern layer 120. The first insulating layer 131 may be formed on an upper portion of the wiring pattern layer 120 that corresponds to the bending area BA.

Thereafter, the first plating layer 310 is partially formed on the wiring pattern layer 120. The first plating layer 310 may be formed on portions of the wiring layer 120 excluding the portion where the first insulating layer 131 is formed. The first plating layer 310 may be formed on portions of the upper surface of the wiring pattern layer 120 that correspond to non-bending areas NBA. The first plating layer 310 may cover the entire wiring pattern layer 120 except for the portion where the first insulating layer 131 is formed. The first plating layer 310 may cover not only the upper surface but also a side surface of the wiring pattern layer 120.

Thereafter, the second insulating layer 132 is formed to cover the first plating layer 310 and the first insulating layer 131. The second insulating layer 132 may cover portions of the base film 110 where the wiring pattern layer 120 is not formed.

Thereafter, the recess portion 140 is formed on a lower surface of the base film 110. The recess portion 140 may be formed at a location corresponding to the first insulating layer 131. The recess portion 140 may be formed in a portion corresponding to the bending area BA.

Meanwhile, the first insulating layer 131 may be formed on the first plating layer 310. In this case, the step of forming the first plating layer 310 precedes, and the step of forming the first insulating layer 131 follows.

Although the above method describes a structure in which the first insulating layer 131 remains included in the final product, the first insulating layer 131 may be removed during the manufacturing process.

First, the wiring pattern layer 120 is formed on a surface of the base film 110.

Thereafter, the first insulating layer 131 is partially formed on the wiring pattern layer 120. The first insulating layer 131 may be formed on an upper portion corresponding to the bending area BA of the wiring pattern layer 120.

Thereafter, the first plating layer 310 is formed on portions of the wiring pattern layer 120 excluding the portion where the first insulating layer 131 is formed. The first plating layer 310 may be formed on a portion of the upper surface of the wiring pattern layer 120 corresponding to a non-bending area NBA.

Thereafter, the first insulating layer 131 is removed, and the second insulating layer 132 is formed to cover the first plating layer 310 and the wiring pattern layer 120 exposed by removal of the first insulating layer 131. The second insulating layer 132 may cover portions of the base film 110 where the wiring pattern layer 120 is not formed. The second insulating layer 132 may not cover part of the first plating layer 310. The second insulating layer 132 may not cover a portion located at the outermost side of the first plating layer 310.

Thereafter, the second plating layer 320 is formed to cover the first plating layer 310 not covered by the second insulating layer 132. The second plating layer 320 may cover the upper surface and side surfaces of the first plating layer 310. The second plating layer 320 may cover side surfaces of the wiring pattern layer 120. The second plating layer 320 may be in contact with the upper surface of the base film 110 or a side surface of the second insulating layer 132. The second plating layer 320 may be formed to be thicker than the first plating layer 310.

Thereafter, the recess portion 140 is formed on the lower surface of the base film 110. The recess portion 140 may be formed using various methods such as laser processing, etching, or cutting. The recess portion 140 may be formed through one or more processing steps. The recess portion 140 may be formed in a portion of the base film 110 that corresponds to the bending area BA.

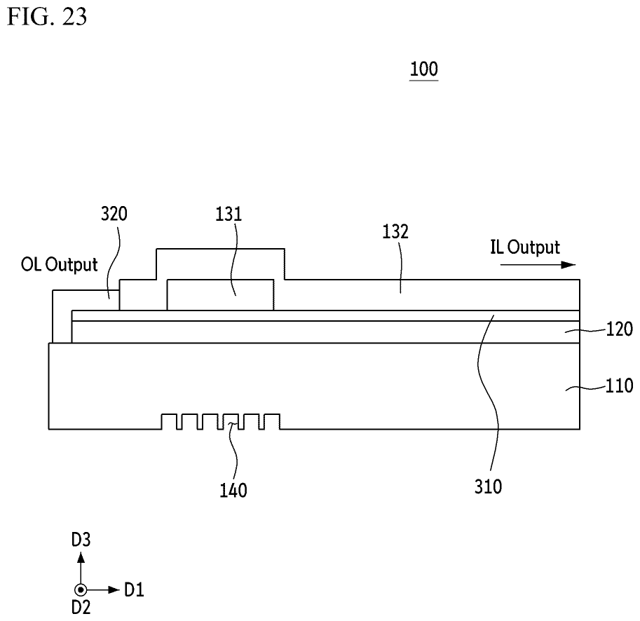

Meanwhile, wiring pattern layers 120 may be formed on both surfaces of the base film 110. Specifically, wiring pattern layers 120 may be formed not only on the upper surface but also on the lower surface of the base film 110. FIG. 25 is a sixth exemplary view for explaining the structure of the FPCB according to some embodiments of the present disclosure. The embodiment of FIG. 25 will hereinafter be described, focusing only on differences from the embodiments of FIGS. 1 through 24, and redundant descriptions of overlapping features with the embodiments of FIGS. 1 through 24 will be omitted.

The wiring pattern layer 120 may be provided in a plurality of layers. For example, the plurality of wiring pattern layers may include a first wiring pattern layer 120 and a second wiring pattern layer 160. The first wiring pattern layer 120 may be defined as the wiring pattern layer formed on the upper surface of the base film 110, and the second wiring pattern layer 160 may be defined as the wiring pattern layer formed on the lower surface of the base film 110.

Protective layers 130 and 170 may be formed on the wiring pattern layers 120 and 160, respectively. The protective layer formed on the first wiring pattern layer 120 may be defined as a first protective layer 130, and the protective layer formed on the second wiring pattern layer 160 may be defined as a second protective layer 170.

The first wiring pattern layer 120 may be formed in the bending area BA and the non-bending areas NBA. The second wiring pattern layer 160 may be formed in the non-bending areas NBA and may not be formed in the bending area BA.

The first protective layer 130 may be formed in the bending area BA and the non-bending areas NBA. The thickness of the first protective layer 130 may vary from region to region. A portion of the first protective layer 130 formed in the bending area BA may be thicker than portions of the first protective layer 130 formed in the non-bending areas NBA. The second protective layer 170 may be formed in the non-bending areas NBA and may not be formed in the bending area BA. The second protective layer 170 may have a uniform thickness from region to region.

The FPCB 100 may further include a plating portion 150. The plating portion 150 may be provided between the first wiring pattern layer 120 and the first protective layer 130. The plating portion 150 may also be provided between the second wiring pattern layer 160 and the second protective layer 170.

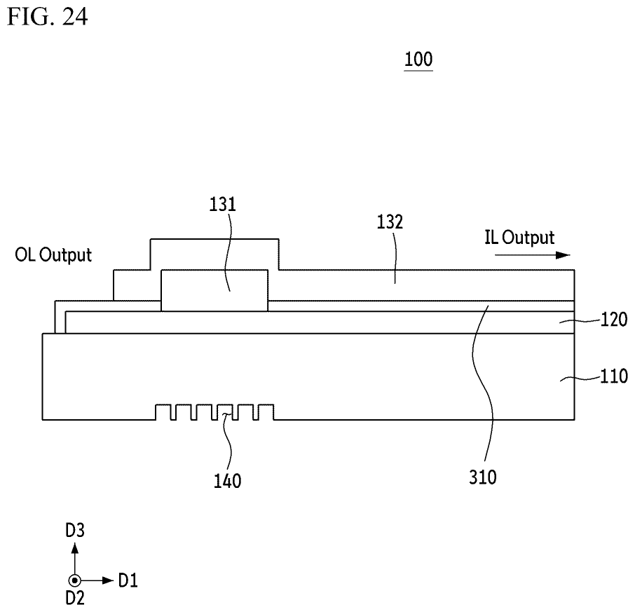

Meanwhile, a semiconductor chip may be mounted on an FPCB 100. The FPCB 100, including the semiconductor chip, may be provided as a semiconductor package. FIG. 26 is an exemplary view for explaining a semiconductor package including the FPCB according to some embodiments of the present disclosure. Referring to FIG. 26, a semiconductor package 400 may include the FPCB 100, a semiconductor chip 410, and bumps 420. The semiconductor package 400 may include one or more semiconductor chips. For example, the semiconductor package 400 may be provided as a COF. The embodiment of FIG. 26 will hereinafter be described, focusing only on differences from the embodiments of FIGS. 1 through 25, and redundant descriptions of overlapping features with the embodiments of FIGS. 1 through 25 will be omitted.

The semiconductor chip 410 may be positioned on the wiring pattern layer 120. The semiconductor chip 410 may be electrically connected to the wiring pattern layer 120 through the bumps 420. The wiring pattern layer 120 may include inner leads. The semiconductor chip 410 may be electrically connected to the inner leads. The inner leads may not be covered by the protective layer 130 and may be exposed to the outside.

The semiconductor chip 410 may be positioned on the upper surface of the base film 110, but the present disclosure is not limited thereto. Alternatively, the semiconductor chip 410 may be disposed on the lower surface of the base film 110. Yet alternatively, semiconductor chips 410 may be disposed on the upper and lower surfaces of the base film 110, respectively.

The semiconductor package 400 may be provided in an electronic device. For example, the electronic device may be a smartphone, a digital camera, or a display device. The semiconductor package 400 may control a camera actuator or a display panel. The semiconductor package 400 may include an application processor (AP) or a display driver integrated circuit (DDI).

Experiments for measuring rebound force of the FPCB according to some embodiments of the present disclosure will hereinafter be described. Specific experimental examples and comparative examples are provided to aid understanding of the present disclosure, but are merely exemplary and do not limit the scope of the appended claims. Various modifications and alterations to these experimental examples are apparent to one of skill in the art within the concept and scope of the present disclosure, and naturally fall within the scope of the claims.

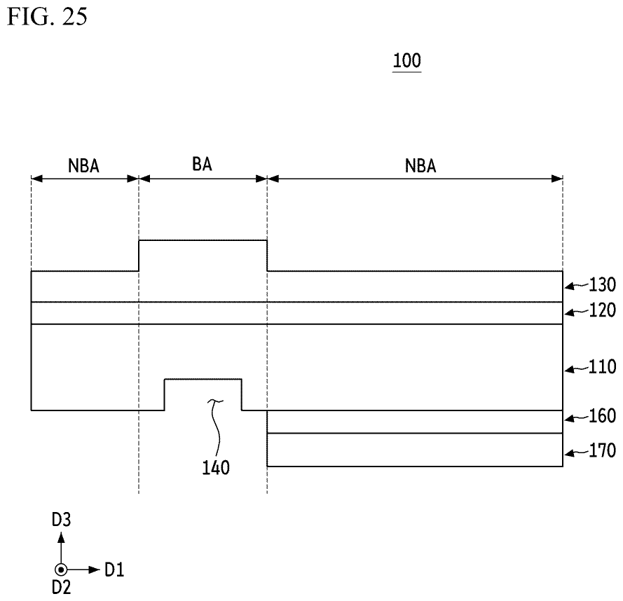

FIG. 27 is a table showing the results of a first experiment for the FPCB according to some embodiments of the present disclosure. The first experiment relates to measuring the rebound forces of line-shaped recess portions. The first experiment compares the rebound forces of Experimental Examples 1 through 5, which are FPCBs 100 including a line-shaped recess portion 140 obtained by the method of the present disclosure, and the rebound force of a comparative example, which is a conventional FPCB with no recess portion.

As the conventional example and Experimental Examples 1 through 5 , products having a size of 48,000 μm in width and 19,000 μm in length were used. The size of the bending areas BA of the FPCBs 100 according to Experimental Examples 1 through 5 was set to 37,850 μm in width and 3,480 μm in length. Here, “width” may be defined as a dimension in a longitudinal direction, and “length” as a dimension in a transverse direction. In addition, in each of Experimental Examples 1 through 5, a wiring pattern layer was formed on a first surface of a base film 110 with a thickness of 35 μm in a third direction D3, and a line-shaped recess portion 140 having a ‘|’-shape was continuously formed from one end to the other end of a second surface of the base film 110. In this case, the width of each formed recess was set to 30 μm.

The rebound forces of the conventional example and Experimental Examples 1 through 5 were measured as follows. First, each product was rolled into a loop shape having a diameter of approximately 10 mm. The rolled product was placed on a lower stage of a material strength tester, and an upper stage of the material strength tester was arranged to contact each product. Then, the upper stage was driven toward the lower stage at a constant speed. Thereafter, the rebound force of each product was measured when the distance between the upper and lower stages reached approximately 1 mm. This measurement method was applied equally to subsequent experiments to be described below.

Referring to FIG. 27, it can be seen that as the processing depth and the number of processed lines (i.e., line quantity [EA]) of each ‘|’-shaped line recess increase, the rebound force tends to decrease. That is, a reduced rebound force can be expected from an FPCB 100 including such a line-shaped recess portion 140, compared to an FPCB not including the recess portion 140.

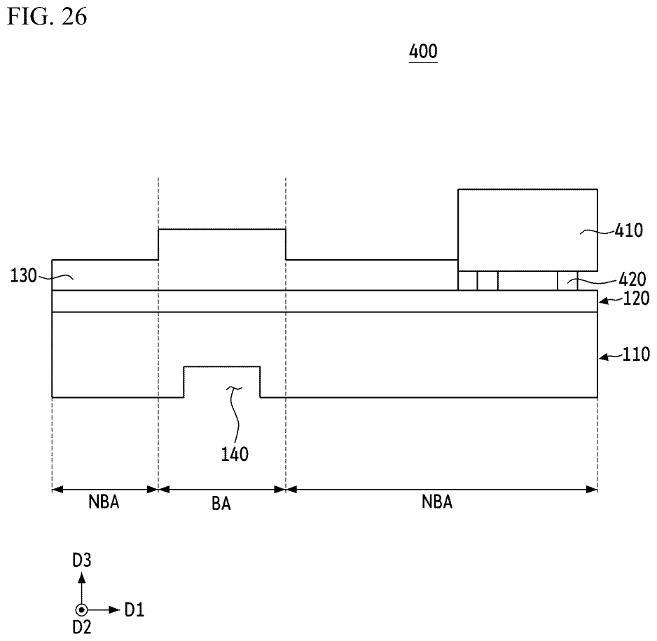

FIG. 28 is a table showing the results of a second experiment for the FPCB according to some embodiments of the present disclosure. The second experiment relates to measuring the rebound forces of line-shaped recess portions. The second experiment compares the rebound forces of recess portions that include a single line-shaped recess with a greater width than its thickness. Each of Experimental Examples 6 through 11 targets an FPCB 100 in which a wiring pattern layer 120 is formed on a first surface of a base film 110 and a ‘|’-shaped recess portion 140 is continuously formed from one end to the other end on a second surface of the base film 110. Here, the size of the FPCBs 100 and the size of the bending areas BA of the FPCBs 100 are the same as those in the first experiment.

Referring to Experimental Examples 6 and 7, it is observed that for a given recess width, the deeper the processing depth, the lower the rebound force. In addition, referring to experimental examples 7 through 12, it is found that for a given processing depth, the narrower the recess width (μm), the lower the rebound force. Meanwhile, if the recess width is beyond the width of the bending areas BA, the reliability of bonding may deteriorate due to sagging of the FPCBs 100.

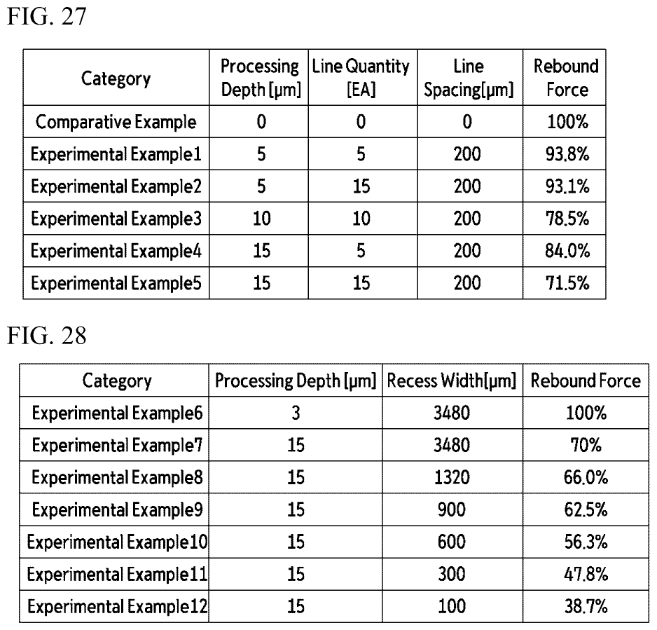

FIG. 29 is a graph showing the results of a third experiment for the FPCB according to some embodiments of the present disclosure. The third experiment relates to measuring the rebound forces of circular dot-type recess portions.

The third experiment compares the rebound forces of recess portions including multiple dot-type recesses formed in the bending area of each FPCB. Each experimental result targets an FPCB 100 in which a wiring pattern layer 120 is formed on a first surface of a base film 110 and a recess portion 140 including multiple dot-type recesses is formed on a second surface of the base film 110. Here, the size of the FPCBs 100 and the size of the bending areas BA of the FPCBs 100 are the same as in the first experiment. In addition, a conventional example targets a conventional FPCB in which no recess portion 140 is formed in the bending area BA.

Referring to FIG. 29, which is a graph showing the results of the third experiment, it is confirmed that when the recess quantity is 1,000 or more, the rebound force decreases, and when the recess quantity is between 2,000 and 6,000, the rebound force decreases by 25% or more compared to the conventional example. Further, when the recess quantity is 7,000 or more, the rebound force decreases by 32% or more compared to the conventional example, confirming that the greater the number of dot-type recesses formed within the bending area BA, the more the rebound force tends to decrease.

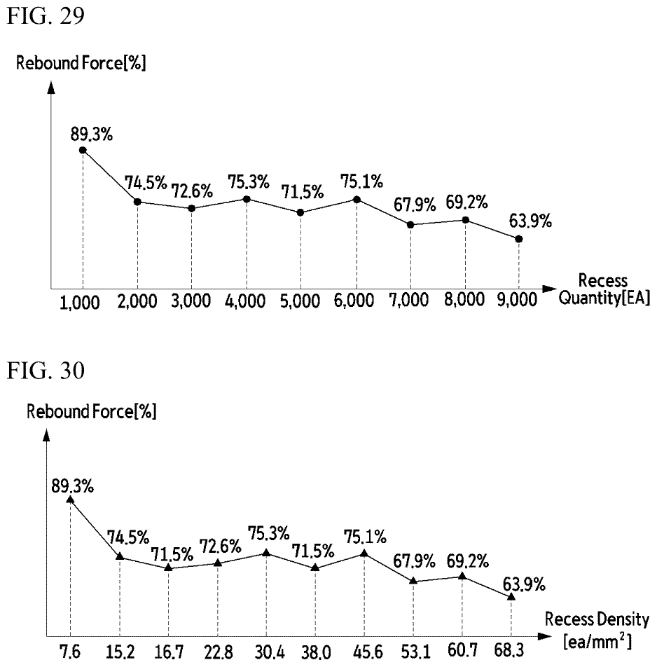

FIG. 30 is a graph showing the results of a fourth experiment for the FPCB according to some embodiments of the present disclosure. The fourth experiment relates to measuring the rebound forces of circular dot-type recess portions. Unlike the third experiment, the fourth experiment compares the rebound forces of recess portions according to the number of recesses per unit area (1 mm²), i.e., recess density (EA/mm²). Each experimental example targets an FPCB 100 in which a wiring pattern layer 120 is formed on a first surface of a base film 110 and a dot-type circular recess portion 140 is formed on a second surface of the base film 110. Here, the size of the FPCBs 100 and the size of the bending areas BA of the FPCBs 100 are the same as those in the first experiment.

Referring to FIG. 30, which shows the results of the fourth experiment, it is demonstrated that as the recess density (EA/mm²) increases, the rebound force tends to decrease. In particular, when the recess density is less than 10, the rebound force improvement effect is insignificant at about 90% compared to the conventional example. However, when the recess density exceeds 10, the rebound force sharply decreases to about 75%. Thus, forming 10 or more recesses per unit area (1 mm²) is effective in improving rebound force characteristics. In addition, although not shown in FIG. 30, it is preferable to form 150 or fewer recesses per unit area. More preferably, forming 120 or fewer recesses per unit area is effective not only in improving rebound force characteristics but also in securing process flowability.

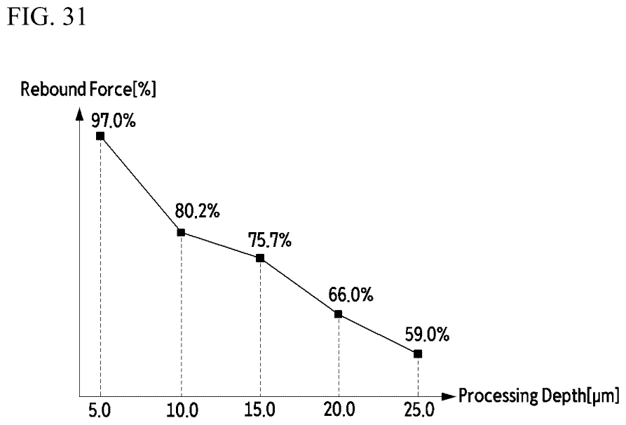

FIG. 31 is a graph showing the results of a fifth experiment for the FPCB according to some embodiments of the present disclosure. The fifth experiment relates to measuring the rebound forces of circular dot-type recess portions. In the fifth experiment, while uniformly maintaining the number of recesses per unit area, the rebound forces of the circular dot-type recess portions were compared depending on changes in processing depth. Each experimental example targets an FPCB 100 in which a wiring pattern layer 120 is formed on a first surface of a base film 110 and a recess portion 140 is formed on a second surface of the base film 110. Here, the size of the FPCBs 100 and the size of the bending areas BA of the FPCBs 100 are the same as those in the first experiment. In addition, the number of recesses per unit area (1 mm²) is about 22.8, and the total number of recesses formed within each recess portion 140 is about 3,000.

Referring to FIG. 31, the results show that the rebound force tends to decrease as the processing depth increases. However, when the processing depth exceeds 60% of the thickness of the base film 110, process flowability may deteriorate during manufacturing. Accordingly, it is preferable to form the processing depth of the recesses to be 10% to 80% of the thickness of the base film 110.

Embodiments of the present disclosure have been described so far with reference to the accompanying drawings. However, the present disclosure is not limited to the above embodiments and may be implemented in various different forms. One of skill in the art will understand that various modifications and alterations can be made without departing from the technical concept or characteristics of the present disclosure. Therefore, the aforementioned embodiments are merely illustrative in every aspect and should not be construed as limiting.

What is claimed is:

1. A flexible printed circuit board (FPCB) comprising:
a base film in which a bending area and a non-bending area are defined;
a first wiring pattern layer formed on a first surface of the base film;
a first protective layer formed on the first wiring pattern layer; and
a recess portion formed in the bending area on a second surface of the base film and including a plurality of recesses,
wherein the plurality of recesses are spaced apart from each other and are formed in a dot shape.

2. A flexible printed circuit board (FPCB) comprising:
a base film in which a bending area and a non-bending area are defined;
a first wiring pattern layer formed on a first surface of the base film;
a first protective layer formed on the first wiring pattern layer; and
a recess portion formed in the bending area on a second surface of the base film and including at least one recess,
wherein the at least one recess is continuously formed in a line shape along a first direction or a second direction of the base film.

3. The FPCB of claim 1, wherein the base film has a width ranging 30 mm to 250 mm in a first direction or a second direction and a thickness ranging from 15 μm to 40 μm in a third direction.

4. The FPCB of claim 1, wherein
at least one bending area is formed on the base film, and
the at least one bending area has a length ranging from 30 mm to 250 mm in a first direction or a second direction and a width ranging from 0.1 mm to 30 mm in the first direction or the second direction.

5. The FPCB of claim 1, wherein the recess portion is formed to be as large as or smaller than the bending area of the base film.

6. The FPCB of claim 1, wherein a recess of the recess portion is formed to have a processing depth smaller than a thickness of the base film in the third direction.

7. The FPCB of claim 1, wherein a recess of the recess portion is formed to have a processing depth of 10% to 80% relative to a thickness of the base film in the third direction.

8. The FPCB of claim 1, wherein a recess of the recess portion is formed with a spacing of 300 μm or less therebetween.

9. The FPCB of claim 1, wherein the plurality of recesses are formed at a density of 10 or more recesses per unit area of 1 mm².

10. The FPCB of claim 9, wherein the plurality of recesses are formed at a density of 150 or fewer recesses per unit area of 1 mm².

11. The FPCB of claim 1, wherein the plurality of recesses have an average pitch of 40 μm to 350 μm.

12. The FPCB of claim 2, wherein the at least one recess is formed to have a width of 10 μm or more in the first direction or the second direction.

13. The FPCB of claim 1, wherein the first protective layer has a thickness greater in a region corresponding to the bending area of the base film than in a region corresponding to the non-bending area of the base film.

14. The FPCB of claim 13, wherein the first protective layer further includes an inclined surface connecting the region corresponding to the bending area of the base film and the region corresponding to the non-bending area of the base film.

15. The FPCB of claim 1, wherein
the first protective layer includes: a first insulating layer provided in a region corresponding to the bending area of the base film; and a second insulating layer covering the first insulating layer, and
the second insulating layer extends to a region corresponding to the non-bending area of the base film.

16. The FPCB of claim 1, wherein
a region where the recess portion is formed includes a plurality of zones, and
the plurality of recesses are formed in at least some of the plurality of zones.

17. The FPCB of claim 16, wherein
the region where the recess portion is formed includes the plurality of zones, and
the plurality of recesses are formed in different numbers in the corresponding zones.

18. The FPCB of claim 1, wherein a width of a recess of the recess portion is equal to or greater than a processing depth of the recess of the recess portion.

19. The FPCB of claim 18, wherein
the recess portion has a multilayer structure,
the multilayer structure includes a first layer and a second layer positioned above the first layer, and
a width of at least one recess located in the second layer is different from a width of at least one recess located in the first layer.

20. The FPCB of claim 19, wherein the width of the at least one recess located in the second layer is smaller than the width of the at least one recess located in the first layer.

21. The FPCB of claim 1, further comprising:
a plating portion formed between the first wiring pattern layer and the first protective layer.

22. The FPCB of claim 21, wherein the plating portion is formed in at least one of the bending area or the non-bending area of the base film.

23. The FPCB of claim 21, wherein the plating portion includes: a first plating layer formed on the first wiring pattern layer and partially covered by the first protective layer; and a second plating layer covering a portion of the first plating layer not covered by the first protective layer.

24. The FPCB of claim 1, further comprising:
a second wiring pattern layer formed on the second surface of the base film; and
a second protective layer formed on the second wiring pattern layer,
wherein the second wiring pattern layer is formed in regions excluding a region where the recess portion is formed.

25. A semiconductor package comprising:
the FPCB of claim 1;
a semiconductor chip mounted on the FPCB; and
bumps electrically connecting the FPCB and the semiconductor chip.

26. An electronic device comprising the semiconductor package of claim 25.
